(19) United States
(12) Patent Application Publication
(10) Pub. No.: US 2003/0021327 A1
(43) Pub. Date: Jan. 30, 2003

(54) Semiconductor surface-emitting laser with integrated photodetector

(76) Inventor: Stefan J. Murry, Houston, TX (US)

Correspondence Address: APPLIED OPTOELECTRONICS, INC., 13111 JESS PIRTLE BLVD., SUGAR LAND, TX, 77478, US

(21) Appl. No.: 09/915,942

(22) Filed: Jul. 25, 2001

(51) Int. Cl. H01S 5/183

(52) U.S. Cl. 372/96

(57) ABSTRACT

A VCSEL device has a VCSEL portion having a bottom laser cavity mirror, a top laser cavity mirror, and an active region disposed between the top and bottom mirrors; and a photodetector deposited directly onto a top surface of the laser structure, without an independent substrate, and situated so that light generated by the laser structure and exiting through the top mirror impinges on said photodetector. The integrated photodetector may be used to monitor the optical power of the light output by the laser, to control the optical power and/or to detect laser failure.

### BACKGROUND OF THE INVENTION

1. Field of the Invention

This invention relates generally to semiconductor lasers and, in particular, to vertical-cavity surface-emitting lasers (VCSEL) and monitor photodetectors used together.

2. Description of the Related Art

The following descriptions and examples are not admitted to be prior art by virtue of their inclusion within this section.

Lasers have a wide range of industrial and scientific uses. There are several types of lasers, including gas lasers, solid-state lasers, liquid (dye) lasers, and free electron lasers. Semiconductor lasers are also in use. The possibility of amplification of electromagnetic waves in a semiconductor superlattice structure, i.e., the possibility of semiconductor diode lasers, was predicted in a seminal paper by R. F. Kazarinov, et al., “Possibility of the Amplification of Electromagnetic Waves in a Semiconductor with a Superlattice,” Soviet Physics Semiconductors, vol. 5, No. 4, pp. 707-709 (October 1971). Semiconductor laser technology has continued to develop since this discovery.

There are a variety of types of semiconductor lasers. Semiconductor lasers may be diode lasers (bipolar) or non-diode lasers such as quantum cascade (QC) lasers (unipolar). Semiconductor lasers of various types may be electrically pumped (EP) (e.g., by a DC or intermittent current), or pumped in other ways, such as by optically pumping (OP) or electron beam pumping. Semiconductor lasers are used for a variety of applications and can be built with different structures and semiconductor materials, such as gallium arsenide.

Additionally, semiconductor lasers may be edge-emitting lasers or surface-emitting lasers (SELs). Edge-emitting semiconductor lasers output their radiation parallel to the wafer surface, while in SELs, the radiation is output perpendicular to the wafer surface. One type of SEL is the vertical-cavity surface-emitting laser (VCSEL). The VCSEL structure usually consists of an active (gain) region sandwiched between two distributed Bragg reflector (DBR) mirrors. The DBR mirrors of a typical VCSEL can be constructed from dielectric or semiconductor layers (or a combination of both, including metal mirror sections). Other types of VCSELs sandwich the active region between metal mirrors. The area between the reflective planes is often referred to as the resonator. The “top” cavity mirror is the exit mirror, and typically has a lower reflectivity than the bottom mirror. A variant on the standard VCSEL, the vertical-external-cavity surface-emitting laser (VECSEL), is also in use. VCSELs are discussed in further detail in Vertical-Cavity Surface-Emitting Lasers: Design, Fabrication, Characterization, and Applications, eds. Carl W. Wilmsen, Henryk Temkin & Larry A Coldren (Cambridge: Cambridge University Press, 1999).

EP semiconductor lasers are typically powered by applying an electrical potential difference across the active region, which causes a current to flow therein. Electrons in the active region attain high energy states as a result of the potential applied. When the electrons spontaneously drop in energy state, photons are produced. Some of those photons travel in a direction perpendicular to the reflective planes of the laser. As a result of the ensuing reflections, the photons can travel through the active region multiple times. When those photons interact with other high energy state electrons, stimulated emission can occur so that two photons with identical characteristics are present. If most electrons encountered by the photons are in the high energy state, the number of photons traveling between the reflective planes tends to increase. A typical laser includes a small difference in reflectivity between its mirrors. The primary laser output is emitted through the reflective plane having lower reflectivity (i.e., the exit or top mirror).

The use of semiconductor diode lasers (both edge-emitting and surface-emitting) for forming a source of optical energy is attractive for a number of reasons. For example, diode lasers have a relatively small volume and consume a small amount of power as compared to conventional laser devices. Further, the diode laser is a monolithic device, and does not require a combination of a resonant cavity with external mirrors and other structures to generate a coherent output laser beam.

Semiconductor lasers such as VCSELs and edge-emitting lasers are used in a variety of applications, including telecommunications and spectroscopy. A typical telecommunications system uses optical fiber to guide modulated radiation from laser to the detection point. In most applications in which a semiconductor laser is used, it is important to be able to monitor the output power of the emitted laser radiation. The measured output power can be used with appropriate control circuitry to control the output power of the laser, or to diagnose failure or other problems with laser operation. For example, the photodetector can be placed in a feedback circuit so that its feedback signal drives a forward biasing circuit to control laser injection current. Or, if a failure in the laser system is diagnosed, tasks may be rerouted to a back-up device or other repair methods may be initiated as appropriate.

It is common to provide a photodetector in the same package as the laser, to function as a check device to verify the proper operation of the laser. This photodetector is sometimes referred to as a “monitor photodetector” or “monitor photodiode,” due to its function in monitoring the output power of the laser.

In many applications, such as telecommunications applications, edge-emitting lasers have been more widely used than VCSELs, which have only recently begun to be commercially available. However, VCSELs have various advantages over edge-emitting lasers for some applications, including telecommunications applications. For example, VCSELs typically have a circular laser beam and a smaller divergence angle than an edge-emitting laser, and can thus be more easily coupled to an optical fiber. Edge-emitting lasers can also be more costly to produce (because they have to be fabricated to a further degree before testing, unlike SELs), and can have lower yield. Thus, VCSELs may be preferred over edge-emitting lasers in some applications. VCSELs typically also have single longitudinal mode operation and high two-dimensional packing density for arrays, making them attractive for applications such as optical recording, telecommunications, and computing.

However, it is more difficult, from a manufacturing point of view, to provide a monitor photodetector for a VCSEL than for an edge-emitting laser. In an edge-emitting laser, the output light is coupled out one edge (front facet) of the device into an optical fiber, with the rear edge (facet) of the diode typically coated with a dielectric stack that has a high reflectivity (approaching 100%). However, some light does come out the back facet. Thus, a monitor photodetector may be mounted and positioned to receive light leaking out of the back facet. Moreover, the amount of light that is coupled out of the back facet is controllable during manufacturing by adjusting the properties of the high reflection (HR) coating that is applied to the back facet.

A monitor photodiode may also be mounted on the back surface of a SEL such as a VCSEL (analogous to mounting the monitor photodiode on the back facet of an edge-emitting laser). Unfortunately, for high-power VCSELs, the back surface is the most efficient way to remove the waste heat from the device, via a heat-sink coupled to the VCSEL's back surface. Mounting a monitor photodiode between the heat-sink and the laser's back surface increases the thermal impedance. This can give rise to an unacceptable degradation in the performance of the laser due to increased operating temperature, as illustrated in FIG. 1. Referring now to FIG. 1, there is shown a prior art VCSEL apparatus 100, comprising a VCSEL array 110 mounted on a photodetector array 120, itself mounted on submount 130. Submount 130 acts as a heat sink, to remove heat generated by VCSELs 110.

In VCSEL system 100, heat removal from VCSELs 110 is less efficient than if photodetectors 120 were not present, because the heat from VCSELs 110 must travel through the photodetector array 120 to get to the heat sink (submount 130). Additionally, in many VCSELs, there may be no emission due to the opaque substrate on which such VCSELs are typically formed.

U.S. Pat. No. 5,953,355 teaches a packaging scheme in which the monitor photodiode is located somewhere else inside the package, physically separated from the VCSEL chip itself. This and other monitor photodiode mounting schemes can be disadvantageous from the perspective of coupling light onto the photodetector. U.S. Pat. No. 5,285,466 teaches a VCSEL design in which lateral horizontally emitted light from the VCSEL is monitored by a monolithically integrated detector diode as an indicator of the axially vertically emitted light from the VCSEL. One problem with this approach is that it requires more area and it also requires a special design for the VCSEL in which some of the cavity light escapes from the mesa sidewalls, which may also reduce the efficiency and output power of the VCSEL.

An alternative position in which to place the monitor photodiode is on top of the VCSEL (or array), interposed between the VCSEL (or array) and the optical fiber(s) that collects the light output. This would resolve both the heat removal problem (since the photodetector would not be between the VCSEL and the heat sink) as well as the geometric problem associated with trying to couple light onto an externally-mounted photodetector. However, as noted by the '466 patent, monolithically integrating a photodiode on the top of the VCSEL requires a structure too complex and costly to manufacture.

Another problem with mounting a typical photodetector grown on a substrate on top of the VCSEL is that typical photodetector substrate materials are not transparent to light, which would make it impossible for light to penetrate into the optical fiber, rendering the device useless for practical application. This problem may be referred to as substrate absorption. Second, conventional photodiode substrates, even if transparent, are too thick to allow the fiber to be brought close enough to the output aperture of the VCSEL to enable useful coupling of the light output into the fiber. Additionally, it is difficult to provide electrical contacts to both the VCSEL and the photodetector, since they are essentially “face-to-face” where both devices need to have electrical contacts.

There is a need, therefore, for improved photodetectors and VCSEL/photodetector apparatuses to permit monitoring of the VCSEL emission.

### BRIEF DESCRIPTION OF THE DRAWINGS

Other features and advantages of the invention will become apparent upon study of the following description, taken in conjunction with the attached FIGS. 1-3.

FIG. 1 shows a prior art VCSEL apparatus comprising a VCSEL mounted on a photodetector, itself mounted on a submount;

FIG. 2 is a cross-sectional view of the layer structure of an integrated VCSEL device, having a VCSEL substrate, a VCSEL, and a monitor photodetector, in accordance with an embodiment of the present invention;

FIG. 3 is a flowchart illustrating the power output control circuit of the VCSEL device of FIG. 2;

FIG. 4 is a top view of the integrated VCSEL device of FIG. 2; and

FIG. 5 is a cross-sectional view illustrating the layer structure of an embodiment of the VCSEL device of FIG. 2 in further detail.

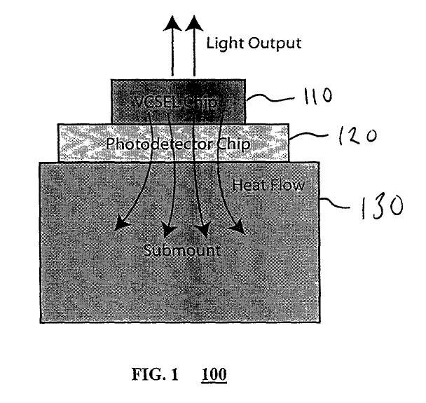

### DETAILED DESCRIPTION OF THE INVENTION

The present invention provides an improved apparatus having a VCSEL and integrated monitor photodetector, and method for integrating a monitor photodetector on the surface of a VCSEL in such a way that it is sufficiently transparent to allow enough light to pass into the fiber, as well as sufficiently thin to allow high-efficiency coupling of the light into the optical fiber, while detecting enough of the laser emission to provide useful monitoring functions. In addition, the present invention does not suffer from the drawbacks described above with respect to the electrical contacts of the two devices.

In an embodiment, the invention involves depositing a simple, albeit low-performance, photodetector structure directly on the top surface of the VCSEL chip. The method of fabricating the improved VCSEL device of the present invention also allows the subsequent application of electrical contacts to both the laser and the photodetector, through conventional processing techniques.

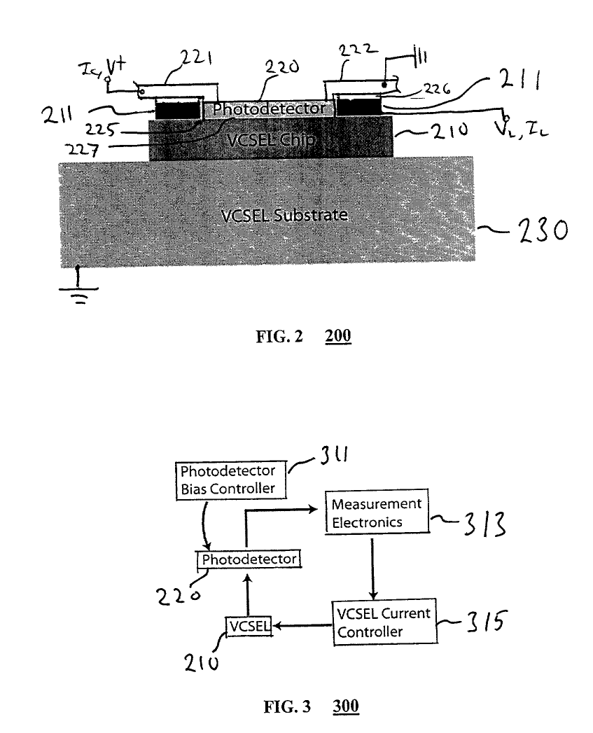

Referring now to FIG. 2, there is shown a cross-sectional view of the layer structure of an integrated VCSEL device, comprising VCSEL substrate 230, VCSEL 210, and monitor photodetector 220, in accordance with an embodiment of the present invention. Substrate 230 may be itself mounted onto a submount (not shown), as will be appreciated. Photodetector electrical contacts 221 and 222, and VCSEL drive current (IL) contact 211, are provided as shown. The photodetector 220 structure is disposed directly on top of the VCSEL 210, utilizing the VCSEL itself as a substrate.

Since the VCSEL chip 210 itself serves as the substrate for the photodetector 220, the problem of substrate absorption and excessive thickness are solved. The improved VCSEL device of the present invention can advantageously be manufactured more easily and inexpensively than other coupled VCSEL-photodetector combinations.

In an embodiment of the invention, photodetector 220 is formed by depositing a layer of germanium on top of the semiconductor laser 210. Germanium is preferable in some applications, including telecommunications applications, due to its bandgap. Telecommunications lasers generally have output wavelengths near 1.55 μm (which corresponds to the minimum attenuation for a commonly used silica optical fiber). A fundamental requirement for semiconductor photodetector materials is that the bandgap of the material must be smaller than the photon energy of the light the photodetector is designed to detect. Germanium has a bandgap energy at 300K of 0.67 eV, while light at 1.55 μm has a photon energy of 0.8 eV. Since the photon energy is larger than the bandgap, the absorption of a photon can promote a carrier from the valence band of the semiconductor to the conduction band, thereby allowing detection.

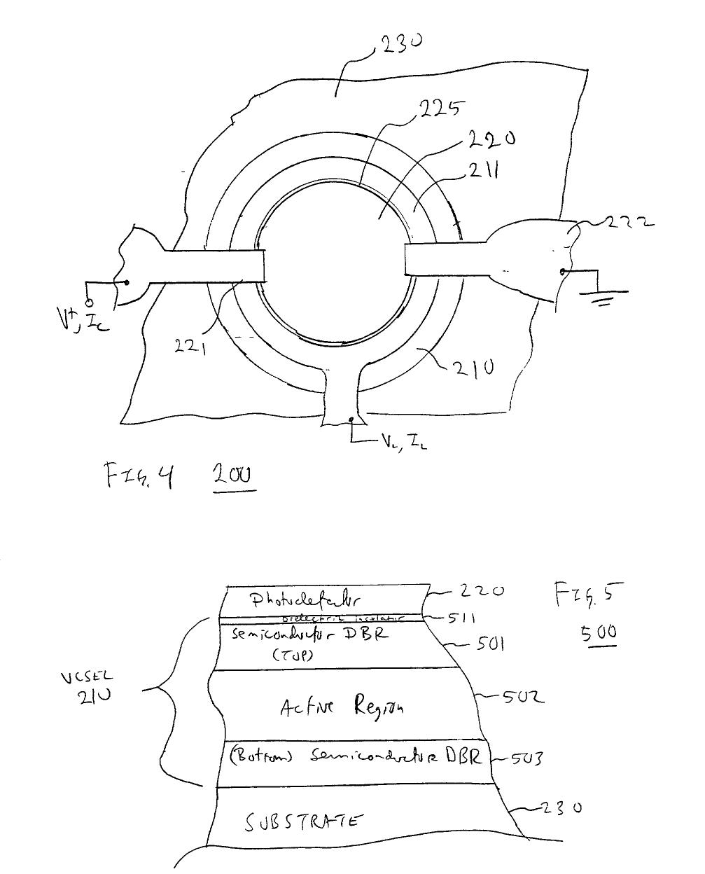

In the embodiment illustrated in cross-section in FIG. 2, terminal 211 is an annular ring deposited onto the top surface of the VCSEL, to which the appropriate laser drive current and voltage IL, VL, are applied. A small gap 225 preferably separates the photodetector 220 from laser power terminal 211. The ground terminal for the laser active region is provided by substrate 230. The two terminals 221 and 222 for operation of photodetector 220 are preferably provided on top of annular laser power terminal 211, with an insulating (e.g. dielectric) layer 226 disposed therebetween. Layer 226 may be, e.g., approximately a few hundred nm thick. These and other features are also illustrated from a top view in FIG. 4.

In an alternative embodiment, terminals 221, 222 and 211 may be arranged differently. For example, terminals 221, 222 may be placed inside (next to) annular terminal 211, on the outside of photodetector layer 220. This embodiment may not be preferred in some applications, because it results in the annular ring terminal 211 is farther away from the laser aperture and active region than otherwise, which can reduce current spreading and thereby impair laser operation. In an alternative embodiment in which current spreading is not a concern, however (e.g., in the case of a VCSEL employing oxide confinement), such an arrangement of terminals 211, 221, 222 may be employed). In alternative embodiments, other suitable arrangements of all necessary electrical terminals may be employed.

As will be appreciated, the top surface of VCSEL 210, onto which the photodetector layer 220 is deposited, is the top surface of the top layer of VCSEL 210. In one embodiment, the top layer of VCSEL 210 is the uppermost DBR layer of the top DBR mirror, for example when the top DBR mirror is a dielectric DBR mirror. In alternative embodiments, there may be a final layer or layers of optical elements on top of the top DBR mirror of the VCSEL. Referring now to FIG. 5, there is shown a cross-sectional view illustrating the layer structure of an embodiment of VCSEL device 200 2 in further detail. As illustrated in FIG. 5, in an embodiment, the top DBR mirror 501 of VCSEL structure 210 is a semiconductor material. In order to isolate the VCSEL active region 502 and top DBR 501 from the effects of the current applied through photodetector terminals 221, 222, a thin insulating (dielectric) layer 511 may be the top layer of the VCSEL 210, directly on top of the top DBR501. For example, a passivation layer (e.g., 511) may serve both passivation functions as well as the insulating function to electrically isolate photodetector layer 220 from VCSEL 210.

Alternatively, one or more optical elements may be between the top DBR layer of VCSEL 210. In various embodiments, VCSEL 210 preferably comprises a bottom DBR 503, an active region 502, and a top DBR 501, so that photodetector 220 is always situated on top of the top DBR 501 (whether or not other VCSEL layers or optical elements, such as dielectric layer 511, are between the top DBR 501 and the photodetector 220). Photodetector 220 is thus necessarily outside of the laser cavity (the region from top DBR 501 to bottom DBR 502, including active region 502), so that photodetector 220 is not within the laser cavity, where its absorption of light would interfere with lasing.

In alternative embodiments, the top and bottom laser cavity mirrors for VCSEL 210 may be dielectric or semiconductor DBR mirrors, or combinations of same; or other types of mirrors, such as metal mirrors. For example, in one embodiment, the top mirror 501 is a dielectric DBR (in which case insulating layer 511 may be omitted); and bottom mirror 503 is a metal mirror.

Various types of suitable photodetectors may be employed with VCSEL device 200. For example, in different embodiments, photodetector 220 is a photoconductor type photodetector, or a photodiode type photodetector. In a photoconductor, light incident on (absorbed by) the detector causes electrons to be promoted from the valence band into the conduction band, where they contribute to reducing the electrical resistivity (i.e. enhancing the conductivity) of the photodetector. The conductivity of the photodetector layer 220, in such an embodiment, is therefore proportional, or at least related in a determinate way, to the incident light intensity. Suitably designed electronics, coupled to terminals 221, 222, can therefore measure the electrical conductivity of the layer to determine the incident light intensity.

A photoconductor type of photodetector may be disposed on VCSEL 210 by using any suitable deposition technique, such as vacuum deposition. In this technique, a solid source of germanium is heated in a high-vacuum environment (with a pressure less than 10⁻⁶ torr, for example) to a temperature above its melting point where it would begin to evaporate. VCSEL chip 210 is placed inside a chamber in such a way that the evaporated germanium vapors impinge on the VCSEL surface, which is at a temperature low enough to cause the vapors to condense on the surface, thereby building up a germanium film 220 on the surface of the VCSEL. If desired, other materials (for example dopants like arsenic or phosphorous) may be co-evaporated along with the germanium in order to created other detectors, including photodiodes. In an embodiment, the photoconducting photodetector layer 220 consisting of germanium is relatively thin, e.g. approximately 0.5 to 1 micron. In an embodiment, the germanium is undoped, when used to form a photoconducting photodetector. In alternative embodiments, materials other than germanium may be employed to form a photoconductor, e.g. some II-VI elements. In one alternative embodiment, InGaAs is employed, instead of germanium, to form photodetector 220. For example, InGaAs may be employed to fabricate a photodiode type photodetector 220.

After the germanium layer is deposited on the substrate, conventional techniques involving lithography and etching may be employed to selectively remove the germanium from areas where they may not be desirable, e.g. outside the VCSEL aperture so that annular contact 211 may be deposited. Electrical contacts 211, as well as 221, 222, may be added to the germanium and/or exposed top surface of VCSEL 210, by thermal evaporation, or other suitable deposition techniques, such as sputtering, molecular beam epitaxy (MBE); liquid phase epitaxy (LPE); or a vapor phase epitaxy (VPE) process such as or metalorganic chemical vapor deposition (MOCVD, also known as MOVPE). In this application the term “deposited” includes both epitaxial types of deposition and other types of deposition, such as sputtering or thermal evaporation.

In accordance with the foregoing fabrication techniques, photodetector 220 may be reproducibly added to the VCSEL structure 210. Such a photodetector is preferably incorporated into a feedback circuit to control and monitor the light output from the VCSEL 210. Referring now to FIG. 3, there is shown a flowchart illustrating the power output control circuit 300 of the VCSEL apparatus 200 of FIG. 2. The terminals 221, 222 of photodetector 220 may be attached to a photodetector control device that properly biases the photodetector, measures the resulting current and/or voltage, and translates this into a suitable control signal. Such of photodetector control device implements the functions, for example, of photodetector bias controller 311, measurement electronics 313, and VCSEL current controller 315, for example. The purpose is to provide a feedback loop that continuously monitors the output of the photodetector 220 to control the input current to the VCSEL 210, and thus the VCSEL optical power output.

In particular, photodetector bias controller 311 applies an appropriate electrical bias (current I_{C} or voltage V+, via terminals 221 and 222, as shown in FIGS. 2 and 4) to photodetector 220. In response to optical energy from VCSEL 210, under bias by unit 311, photodetector 220 generates an analog electrical signal corresponding (related in a known way) to the optical power intensity to the intensity of light impinging on photodetector 220. For example, voltage and/or current across/through terminals 221 and 222 may be used by measurement electronics to generate a corresponding digital signal, which can be applied to VCSEL current controller 315. VCSEL current controller 315, in turn, generates a suitable analog input current IL to annular terminal 211, to maintain or adjust the output optical power of VCSEL 210.

The present invention therefore comprises a semiconductor surface-emitting laser apparatus comprising both a laser structure (e.g., VCSEL 210) and a photodetector (e.g., 220) deposited directly onto a top surface of the laser structure. The laser structure has a bottom laser cavity mirror (e.g., DBR 503, FIG. 5), a top laser cavity mirror (e.g., 501), and an active region (e.g., 502) disposed between the top and bottom mirrors. The laser structure has an output aperture for emitting the light generated by the laser structure and exiting through the top mirror. The laser structure has a top surface, which is either the top surface of the top mirror, or the top surface of one or more layers or optical elements themselves disposed on the top mirror. Thus, the top surface of the layer is always above, or on top of, the top mirror, whether or not there are other layers between the top mirror and the top surface. The photodetector does not have an independent substrate, since it is deposited directly onto the VCSEL, i.e. uses the top surface of VCSEL itself as its substrate. It is deposited directly onto the top surface, over the output aperture of the laser. Thus, the photodetector is situated so that light generated by the VCSEL and exiting through the top mirror of the VCSEL impinges on (passes through) the photodetector, so that it may be detected by the photodetector when it is properly biased.

Accordingly, the photodetector integrated with the VCSEL of the present invention may be utilized to monitor and regulate the optical power of the output laser light. This is done by biasing the photodetector 220 via the first and second electrical photodetector contacts (221, 222), e.g., with a constant voltage V+; and then measuring an electrical output signal (e.g., current I_{C}) from the photodetector (220) in response to light impinging thereon. As will be appreciated, as the light incident on (and thus absorbed by) a photoconducting type photodetector 220 increases, the conductivity of the photodetector also increases. Thus, given a constant bias voltage V+, a greater optical power results in lower resistivity, and thus greater measured photodetector current I_{C}. Accordingly, measured current is directly related to the optical power. This current can be used to regulate the drive current applied to the active region of the laser structure. For example, it may be converted to a digital value, and then compared to a corresponding ideal or target value for the desired optical power, and used to increase, decrease, or maintain the current drive current being applied. Thus, the drive current is regulated in accordance with the electrical output signal from the photodetector.

In an alternative embodiment, the signal generated by measurement electronics module 313 may be employed not to regulate, via negative feedback, the VCSEL optical power output, but to diagnose VCSEL failure. For example, a very crude photodetector 220 may be employed which may not be suitable to accurately monitor and thus regulate the optical output power, but which may nevertheless be sufficient to detect when optical output power drops below some minimum threshold. Such a measurement may be used to determine (and thus indicate) laser failure. For example, if the measured photodetector current I_{C}, for a given bias voltage V+, falls below a predetermined current threshold (electrical magnitude threshold) corresponding to an optical power threshold indicating laser failure, then laser failure can be determined. Corrective or diagnostic action may then be taken based on this determination and indication.

The VCSEL device comprising both VCSEL 210 and photodetector 220 may be one of a plurality (e.g., an array) of VCSELs fabricated onto VCSEL substrate 230.

In an alternative embodiment, photodetector 220 is a photodiode type photodetector. For example, photodetector 220 may have both n and p layers to form a photodiode. This may be done by depositing a suitably doped germanium n layer and a suitably doped germanium p layer. (Alternatively, as noted above, InGaAs may be employed, instead of germanium, to fabricate photodetector 220 as a photodiode type photodetector.) In this case, terminals 221 and 222 are configured to provide the appropriate connection to the two layers and photodetector bias controller 311 is suitable to appropriately bias the photodiode. To connect terminals 221 and 222 to the two layers, for example, terminal 221 may be electrically coupled, as illustrated in FIG. 2, directly to the top layer of photodetector 220; while terminal 222 is electrically coupled to the bottom layer through an opening thereto etched into the top layer of the photodetector.

In another alternative embodiment, a photodetector layer may be formed during epitaxial growth of part of the laser structure itself. For example, a photodetector layer may be grown somewhere in the middle of the top DBR layers. Such an embodiment may be preferably from in that the photodetector layer can be epitaxially fabricated during epitaxial growth of the top DBR layer, but may not be preferred, in some applications and designs, if the photodetector layer unacceptably interferes with lasing action, since it is partly in the laser cavity. In such an embodiment, the photodetector may be considered to be part of the VCSEL, in its top section, e.g. sandwiched between top DBR layers. The photodetector may also be considered in this case to be on top of the VCSEL, i.e. on top of the VCSEL consisting of the bottom mirror, active region, and bottom portion of the top DBR; with extra top DBR layers on top of the photodetector.

The present invention, therefore, is well adapted to carry out the objects and attain the ends and advantages mentioned, as well as others inherent therein. While the invention has been depicted and described and is defined by reference to particular preferred embodiments of the invention, such references do not imply a limitation on the invention, and no such limitation is to be inferred. The invention is capable of considerable modification, alteration and equivalents in form and function, as will occur to those ordinarily skilled in the pertinent arts. The depicted and described preferred embodiments of the invention are exemplary only and are not exhaustive of the scope of the invention. Consequently, the invention is intended to be limited only by the spirit and scope of the appended claims (if any), giving full cognizance to equivalents in all respects.

What is claimed is:

1. A semiconductor surface-emitting laser apparatus comprising:
(a) a laser structure comprising a bottom laser cavity mirror, a top laser cavity mirror, and an active region disposed between the top and bottom mirrors; and
(b) a photodetector deposited directly onto a top surface of the laser structure, without an independent substrate, and situated so that light generated by the laser structure and exiting through the top mirror impinges on said photodetector.

2. The laser apparatus of claim 1, wherein the top mirror is a dielectric distributed Bragg reflector (DBR) mirror.

3. The laser apparatus of claim 1, wherein the top and bottom mirrors are DBR mirrors.

4. The laser apparatus of claim 1, wherein the top mirror is a dielectric DBR mirror.

5. The laser apparatus of claim 1, wherein the bottom mirror comprises a metal mirror.

6. The laser apparatus of claim 1, wherein:
the laser structure further comprises an insulating layer disposed on top of the top mirror; and
the top surface of the laser structure is a top surface of the insulating layer, whereby the photodetector is deposited directly onto the top surface of the insulating layer, without an independent substrate.

7. The laser apparatus of claim 6, wherein the top mirror is a semiconductor DBR mirror and the insulating layer is a dielectric layer.

8. The laser apparatus of claim 1, wherein the laser structure is a vertical-cavity surface-emitting laser (VCSEL).

9. The laser apparatus of claim 1, wherein the photodetector is a photoconducting type photodetector.

10. The laser apparatus of claim 9, wherein the photodetector comprises a layer of germanium.

11. The laser apparatus of claim 1, wherein the photodetector is a photodiode type photodetector.

12. The laser apparatus of claim 11, wherein the photodetector comprises an n-type layer of germanium and a p-type layer of germanium.

13. The laser apparatus of claim 11, wherein the photodetector comprises an n-type layer of InGaAs and a p-type layer of InGaAs.

14. The laser apparatus of claim 1, wherein the laser structure is an electrically-pumped (EP) VCSEL, the laser apparatus further comprising:
a drive current contact for providing a drive current to the active region of the laser structure; and
first and second photodetector contacts for providing a bias to the photodetector and for measuring an electrical output signal from the photodetector in response to light impinging thereon.

15. The laser apparatus of claim 1, wherein:
the laser structure is an electrically-pumped (EP) VCSEL, the laser apparatus further comprising:
a drive current contact for providing a drive current to the active region of the laser structure;
first and second photodetector contacts for providing a bias to the photodetector and for measuring an electrical output signal from the photodetector in response to light impinging thereon; and
a dielectric insulating layer disposed on top of the top mirror;
further wherein:
the top surface of the laser structure is a top surface of the insulating layer, whereby the photodetector is deposited directly onto the top surface of the insulating layer, without an independent substrate; and
the top mirror is a semiconductor DBR mirror.

16. The laser apparatus of claim 15, wherein the photodetector is a photoconducting type photodetector comprising a layer of germanium.

17. A method for producing a semiconductor surface-emitting laser apparatus, the method comprising the steps of:
(a) providing a laser structure comprising a bottom laser cavity mirror, a top laser cavity mirror, and an active region disposed between the top and bottom mirrors, the laser structure having an output aperture for emitting light generated by the laser structure and exiting through said top mirror; and
(b) depositing a photodetector directly onto a top surface of the laser structure over the output aperture, so that said light emitted through said aperture impinges on said photodetector.

18. The method of claim 17, wherein step (a) comprises the steps of epitaxially growing the bottom mirror, active region, and top mirror on a substrate.

19. The method of claim 17, wherein step (b) comprises the step of depositing the photodetector onto the top surface of the laser structure by thermal evaporation.

20. The method of claim 17, wherein step (b) comprises the step of depositing the photodetector onto the top surface of the laser structure by sputtering.

21. The method of claim 17, wherein the top and bottom mirrors are DBR mirrors.

22. The method of claim 17, wherein the top mirror is a dielectric DBR mirror.

23. The method of claim 17, wherein the bottom mirror comprises a metal mirror.

24. The method of claim 17, wherein the laser structure is a vertical-cavity surface-emitting laser (VCSEL).

25. The method of claim 17, wherein the photodetector is a photoconducting type photodetector.

26. The method of claim 25, wherein the photodetector comprises a layer of germanium.

27. The method of claim 17, wherein the photodetector is a photodiode type photodetector.

28. The method of claim 27, wherein the photodetector comprises an n-type layer of germanium and a p-type layer of germanium.

29. The method of claim 27, wherein the photodetector comprises an n-type layer of InGaAs and a p-type layer of InGaAs.

30. The method of claim 17, wherein the laser structure is an electrically-pumped (EP) VCSEL, the laser apparatus further comprising:
a drive current contact for providing a drive current to the active region of the laser structure; and
first and second photodetector contacts for providing a bias to the photodetector and for measuring an electrical output signal from the photodetector in response to light impinging thereon;
the method comprising the further steps of:
biasing the photodetector via the first and second electrical photodetector contacts;
measuring an electrical output signal from the photodetector in response to light impinging thereon; and
regulating the drive current applied to the laser structure via the drive current contact in accordance with the electrical output signal from the photodetector.

31. The method of claim 17, wherein the laser structure is an electrically-pumped (EP) VCSEL, the laser apparatus further comprising:
first and second photodetector contacts for providing a bias to the photodetector and for measuring an electrical output signal from the photodetector in response to light impinging thereon;
the method comprising the further steps of:
biasing the photodetector via the first and second electrical photodetector contacts;
measuring an electrical output signal from the photodetector in response to light impinging thereon;
comparing the magnitude of the electrical output signal to an electrical magnitude threshold corresponding to an optical power threshold; and
determining laser failure if said comparison indicates that the optical power of said light is below the optical power threshold.

32. A semiconductor surface-emitting laser apparatus comprising:
(a) a laser structure comprising a bottom laser cavity mirror, a top laser cavity mirror, and an active region disposed between the top and bottom mirrors; and
(b) a photodetector deposited directly onto a top surface of the laser structure, without an independent substrate, and situated so that light generated by the laser structure and exiting through the top mirror impinges on said photodetector.
